(19) United States
(12) Patent Application Publication
(10) Pub. No.: US 2009/0294833 A1
(43) Pub. Date: Dec. 3, 2009

(54) Semiconductor memory device and method of fabricating the same

(76) Inventor: Yong-Shik Kim, Seoul (KR)

Correspondence Address: LEE & MORSE, P.C., 3141 FAIRVIEW PARK DRIVE, SUITE 500, FALLS CHURCH, VA, 22042, US

(21) Appl. No.: 12/453,803

(22) Filed: May 22, 2009

(30) Foreign Application Priority Data
Jun. 3, 2008 (KR) 10-2008-0052248

(51) Int. Cl. H01L 29/792

(52) U.S. Cl. 257/324; 257/E29.309

(57) ABSTRACT

A semiconductor memory device includes a memory substrate including memory transistors and vertical active pillars, the vertical active pillars defining active regions of the memory transistors, a peripheral circuit substrate including peripheral circuit transistors, a bonding layer interposed between the memory substrate and the peripheral circuit substrate, and a connection structure electrically connecting the memory transistors to the peripheral circuit transistors.

### BACKGROUND

1. Field of the Invention

Example embodiments relate to semiconductor memory devices and methods of fabricating the same. More specifically, example embodiments relate to a semiconductor memory device including vertical active pillars and a method of fabricating the same.

2. Description of the Related Art

A unit cell of a typical semiconductor memory device may include at least one transistor and at least one information storage unit. For example, a unit cell of a dynamic random access memory (DRAM) may use one capacitor as an information storage unit, and a unit cell of a static random access memory (SRAM) may use a flip-flop circuit with transistors as an information storage unit.

With the increase in integration density of semiconductor devices, various technical problems have been encountered. For example, with the continuous decrease in unit cell area of a DRAM, it has become more difficult to secure sufficient capacitance of a capacitor. Accordingly, a capacitorless DRAM has been suggested. A conventional capacitorless DRAM may use a semiconductor substrate as a storage node without using a capacitor in order to decrease the area of a unit cell and simplify a fabrication process thereof.

The conventional capacitorless DRAM, however, may include a silicon-on-insulator (SOI) substrate. Since the SOI substrate may be expensive, fabrication costs of the conventional capacitorless DRAM may increase.

### SUMMARY

Example embodiments are therefore directed to a semiconductor memory device and a method of fabricating the same, which substantially overcome one or more of the problems due to the limitations and disadvantages of the related art.

It is therefore a feature of an embodiment to provide a semiconductor memory device with vertical active pillars.

It is therefore another feature of an embodiment to provide a method of fabricating a semiconductor memory device with vertical active pillars.

At least one of the above and other features and advantages may be realized by providing a semiconductor memory device, including a memory substrate having memory transistors and vertical active pillars, the vertical active pillars defining active regions of the memory transistors, a peripheral circuit substrate having peripheral circuit transistors, a bonding layer interposed between the memory substrate and the peripheral circuit substrate, and a connection structure electrically connecting the memory transistors to the peripheral circuit transistors.

The active pillars may be single-crystalline structures extending vertically with respect to the memory substrate, and the memory transistors may have vertical transistor structures. Each of the active pillars may include a source region and a drain region spaced apart from each other, and a channel region between the source region and the drain region. The source region and the drain region may have a same conductivity type and may be spaced apart from each other along a direction normal to the memory substrate, and the source region and the channel region may have different conductivity types. Each memory transistor may include a gate pattern surrounding the active pillar and a gate insulating layer interposed between the gate pattern and the active pillar, the source and drain regions being at lower and upper portions of the active pillar, respectively. The channel region may be electrically isolated by the gate insulating layer, the source region, and the drain region, the channel region being configured to store charges. The gate insulating layer may include a charge storage structure for storing charges. The gate insulating layer may include a tunnel insulating layer, a charge storage layer, and a blocking insulating layer. A thickness of the gate pattern may be smaller than a length of the active pillar, the thickness and length being measured along a direction normal to the memory substrate.

A distance between a bottom surface of the gate pattern and the bonding layer may be smaller than a distance between a top surface of the source region and the bonding layer, the bottom surface of the gate pattern facing the bonding layer, and the top surface of the source region facing away from the bonding layer. The memory substrate may include a common source region connecting the source regions of the active pillars. Each of the memory transistors may include a gate pattern surrounding the active pillar, and the semiconductor memory device may further include a wordline structure connected to the gate pattern, a bitline structure connected to the drain regions, and a source structure connected to a common source region, wherein the wordline structure, the bitline structure, and the source structure are electrically connected to the peripheral circuit transistor via the connection structure. The connection structure may include a plug penetrating at least the bonding layer, the plug being external to the memory substrate.

At least one of the above and other features and advantages may be also realized by providing a method of fabricating a semiconductor memory device, including forming a memory substrate having memory transistors and vertical active pillars, such that the vertical active pillars define active regions of the memory transistors, forming a peripheral circuit substrate having peripheral circuit transistors, forming a bonding layer interposed between the memory substrate and the peripheral circuit substrate, and forming a connection structure electrically connecting the memory transistors to the peripheral circuit transistors.

The method may further include providing a base substrate including a source layer, a channel layer, and a drain layer, bonding the base substrate to the peripheral circuit substrate via the bonding layer, successively patterning the drain layer, the channel layer, and the source layer to form the vertical active pillars, such that the active pillars include a drain region, a channel region, and a source region, forming a gate pattern to surround the active pillars, such that the memory transistors are defined, and forming the connection structure to electrically connect the gate pattern, the drain region, and the source region to the peripheral circuit transistors. The method may further include, before forming the active pillars, removing a portion of the base substrate to leave at least the source layer, the channel layer, and the drain layer on the bonding layer. Forming the active pillars may include forming a trench by patterning the base substrate left on the bonding layer to expose at least the source layer, such that the bottom of the trench is lower than a top surface of the source layer.

The method may further include, before forming the gate pattern, patterning the base substrate down to a top surface of the bonding layer to form the memory substrate to be used as a cell array region, the memory substrate including a common source region commonly connected to the source regions of the active pillars. The source layer and the drain layer may be formed by ion implantation processes performed under different ion energy conditions, and forming the gate pattern may include forming a gate insulating layer to conformally cover the active pillars, forming a gate conductive layer on the gate insulating layer, and patterning the gate conductive layer to form the gate patterns linearly arranged to surround the active pillars. The connection structure may include at least one plug configured to penetrate the bonding layer, the method further comprising forming a wordline structure connected to the gate pattern, a bitline structure connected to the drain region, and a source structure connected to the common source region, wherein the connection structure is formed through forming the wordline structure, the bitline structure, and the source structure.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a top plan view of a portion of a cell array of a semiconductor device according to example embodiments;

FIG. 2 illustrates a cross-sectional view along line I-I′ in FIG. 1;

FIG. 3 illustrates a cross-sectional view along line II-II′ in FIG. 1;

FIG. 4 illustrates a cross-sectional view along line III-III′ in FIG. 1;

FIG. 5 illustrates a perspective view of one memory cell in FIG. 1;

FIG. 6 illustrates a perspective view of a portion of a gate insulating layer in one memory cell in FIG. 1;

FIG. 7 illustrates a flowchart of a method of fabricating a semiconductor memory device according to example embodiments;

FIGS. 8A through 8C illustrate cross-sectional views of a method of fabricating a bonded substrate according to example embodiments;

FIGS. 9A through 14A illustrate top plan views of a method of fabricating a semiconductor memory device according to example embodiments;

FIGS. 9B through 14B illustrate cross-sectional views along lines I-I′ of respective FIGS. 9A through 14A;

FIG. 15 illustrates a block diagram of an electronic system including a semiconductor device according to example embodiments; and

FIG. 16 illustrates a block diagram of a memory system including a semiconductor device according to example embodiments.

### DETAILED DESCRIPTION OF THE EMBODIMENTS

Korean Patent Application No. 10-2008-0052248, filed on Jun. 3, 2008, in the Korean Intellectual Property Office, and entitled: “Semiconductor Memory Device and Method of Fabricating the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

As used herein, the expressions “at least one,” “one or more,” and “and/or” are open-ended expressions that are both conjunctive and disjunctive in operation. Further, as used herein, the terms “a” and “an” are open terms that may be used in conjunction with singular items or with plural items.

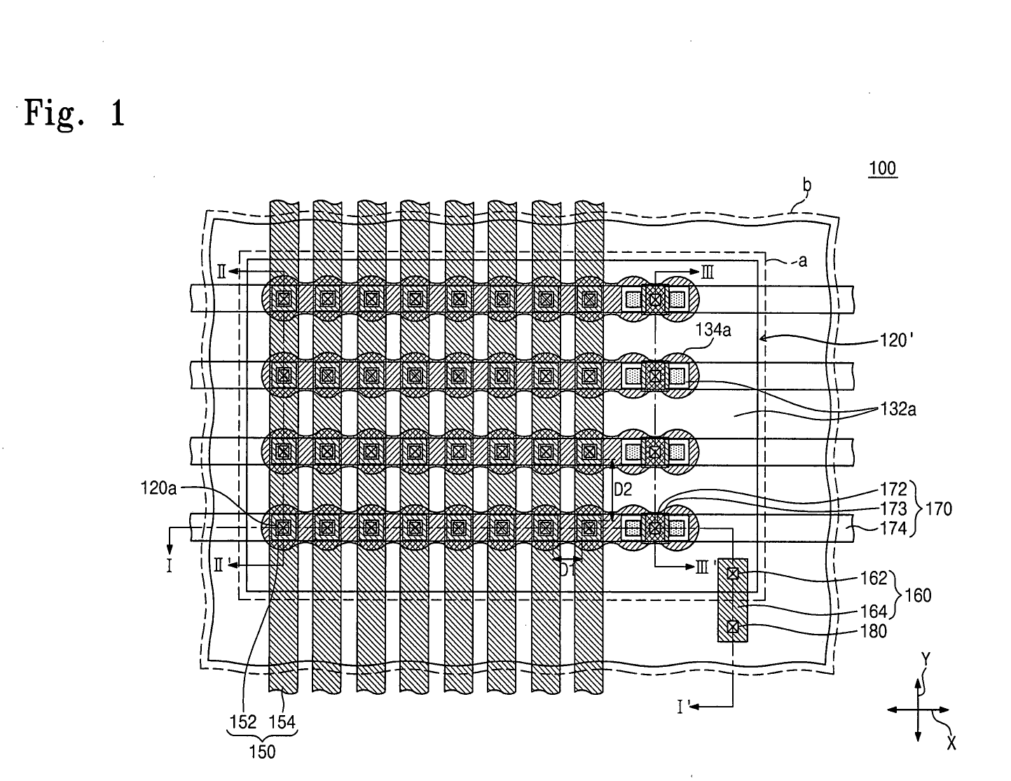

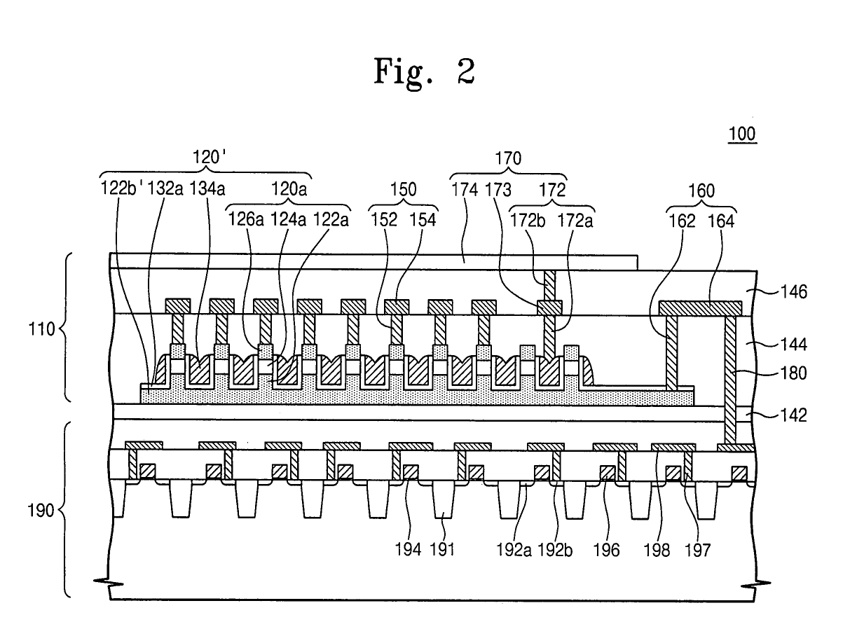

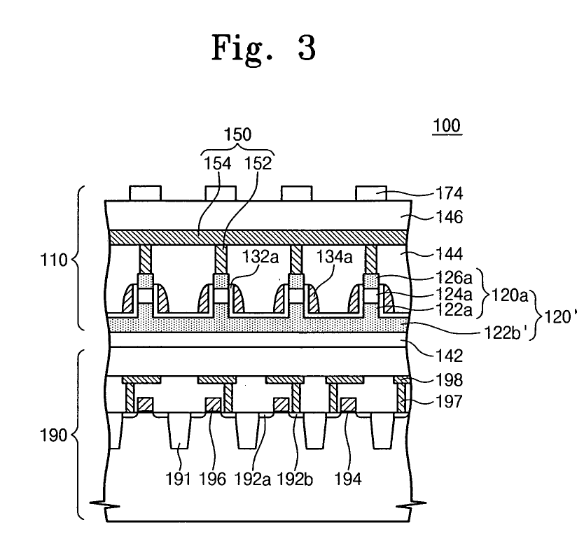

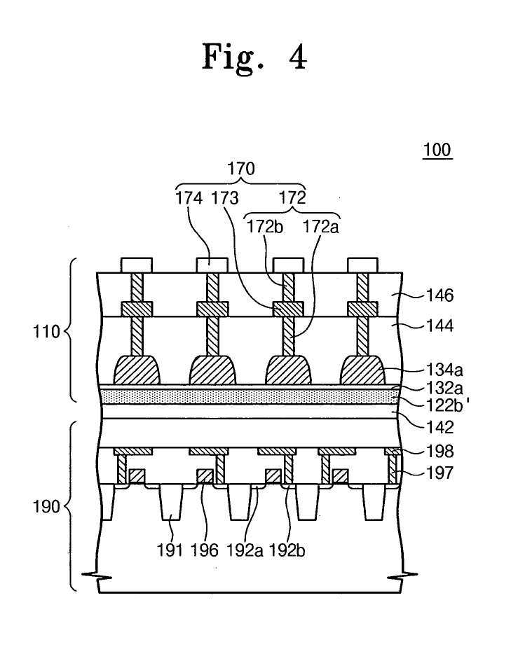

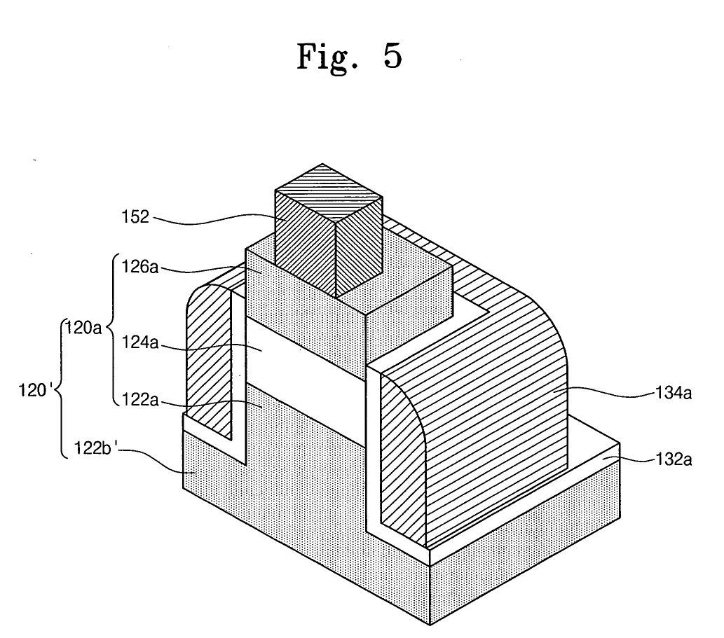

FIG. 1 illustrates a top plan view of a portion of a cell array of a semiconductor device according to example embodiments. FIGS. 2 through 4 illustrate cross-sectional views along lines I-I′, II-II′, and III-III′ of FIG. 1, respectively. FIG. 5 illustrates a perspective view of one memory cell in FIG. 1.

Referring to FIGS. 1 through 5, a semiconductor memory device 100 may include a top architecture 110 including memory transistors and a bottom architecture (hereinafter referred to as “peripheral circuit substrate”) 190 including peripheral circuit transistors for operating the memory transistors. The top architecture 110 may include a cell array region “a” and a peripheral circuit region “b”. As illustrated in FIG. 1, the cell array region “a” may be a region on a memory substrate 120′ having the memory transistors, and the peripheral circuit region “b” may be an outer region with respect to the memory substrate 120′, e.g., the peripheral circuit region “b” may surround the cell array region “a.” The peripheral circuit region “b” may be a region where a connection structure may be formed to connect the memory transistors with the peripheral circuit transistors. The configurations of the connection structure will be described in detail later.

As illustrated in FIGS. 2 and 5, the memory substrate 120′ may include vertical active pillars 120a used as active regions of the memory transistors. The active pillars 120a may be a single-crystalline semiconductor which may extend vertically, i.e., along a direction substantially normal to the xy-plane illustrated in FIG. 1, from a common source region 122b′. For example, the active pillars 120a, e.g., each of the active pillars 120a, may have a circular cross section, e.g., in the xy-plane illustrated in FIG. 1. In another example, the active pillars 120a, e.g., each of the active pillars 120a, may have a tetragonal cross section.

The active pillars 120a may be disposed to have a lattice shape. For example, as shown in FIG. 1, the active pillars 120a may be spaced apart from one another in a first direction X and a second direction Y intersecting the first direction X. A distance between adjacent active pillars 120a disposed in the first direction X (hereinafter referred to as “a first distance D1”) may be shorter than a distance between adjacent active pillars 120a disposed in the second direction Y (hereinafter referred to as “a second distance D2”).

Each of the active pillars 120a may include a source region 122a, a channel region 124a, and a drain region 126a. As illustrated in FIGS. 2 and 5, the source region 122a may be formed to extend upwardly, i.e., vertically, from the common source region 122b′. Accordingly, the respective source regions 122a of the active pillars 120a may be commonly connected to the common source region 122b′. The drain region 126a may be disposed on the source region 122a, and the channel region 124a may be interposed between the source region 122a and the drain region 126a. The source region 122a and the drain 126a may be made of a first conductivity type material (e.g., N-type material), and the channel region 124a may be made of a second conductivity type material (e.g., P-type material) that may be different from the first conductivity type material.

As illustrated in FIGS. 2 and 5, the top architecture 110 may further include a gate insulating pattern 132a and gate conductive patterns 134a. The gate conductive patterns 134a may be disposed at the circumference of the active pillars 120a, e.g., the gate conductive patterns 134a may surround each active pillar 120a, and the gate insulating pattern 132a may be interposed between the active pillars 120a and the gate conductive patterns 134a, e.g., the gate insulating pattern 132 may extend along the entire circumference of the active pillars 120a between the gate conductive patterns 134a and the active pillars 120a. A thickness of each of the gate conductive patterns 134a, i.e., as measured along a normal to the xy-plane, may be shorter than a length of each of the active pillars 120a, i.e., as measured along a normal to the xy-plane. For example, as illustrated in FIG. 1, one gate conductive pattern 134a may be formed to surround a plurality of active pillars 120a disposed in the first direction X. Accordingly, each of the gate conductive patterns 134a may have a line shape, e.g., extending in the first direction X, and may be spaced apart from an adjacent gate conductive pattern 134a along the second direction Y. As set forth above, since the second distance D2 may be greater than the first distance D1, the gate conductive patterns 134a may be spaced apart from one another by the second distance D2, as illustrated in FIG. 1.

A top surface of the gate conductive patterns 134a, i.e., a surface facing away from the common source region 122b′, may be lower than those of the active pillars 120a. In other words, a distance between the top surface of the gate conductive patterns 134a to a reference point on a bottom of the common source region 122b′may be smaller than a distance between a top surface of the active pillars 120a, i.e., a top surface of the drain 126a facing away from the common source region 122b′, and the reference point on the bottom of the common source region 122b′. In addition, a bottom surface of the gate conductive patterns 134a, i.e., a surface opposite the top surface of the gate conductive patterns 134a, may be higher than a top surface of the common source region 122b′. In other words, a distance between the bottom surface of the gate conductive patterns 134a to the reference point on the bottom of the common source region 122b′ may be larger than a distance between the top surface of the common source region 122b′, i.e., a surface opposite the bottom of the common source region 122b′. For example, as illustrated in FIG. 5, a portion of the gate insulating pattern 132a may be interposed between the bottom surface of the gate conductive patterns 134a and the top surface of the common source region 122b′.

The gate insulating pattern 132a surrounding the circumference, e.g., the entire circumference, of the active pillars 120a may be formed to cover, e.g., completely overlap, at least a side surface, i.e., a surface perpendicular to the top surface of the active pillar 120a, of the channel region 124a of the active pillars 120a. Thus, the channel region 124a may be isolated electrically by the source region 122a, the drain region 126a, and the gate insulating pattern 132a to be used as a charge storage element of a capacitorless memory device, e.g., DRAM.

The top architecture 110 may further include a bitline structure 150, a source line structure 160, and a wordline structure 170. The bitline structure 150 may include first plugs 152 and bitlines 154. The bitlines 154 may be disposed on a first interlayer dielectric 144 to cross over the gate conductive pattern 134a, i.e., along the second direction Y. The bitlines 154 may be electrically connected to drain regions 126a of the active pillars 120a via the first plugs 152, respectively. The source line structure 160 may include second plugs 162 and a source line 164. The source line 164 may be disposed on the first interlayer dielectric 144 along the second direction Y, i.e., to be parallel with the bitlines 154, as illustrated in FIG. 1. The source line 164 may be electrically connected to the common source region 122b′ via the second plugs 162. The wordline structure 170 may include third plugs 172 and wordlines 174. The third plugs 172 may be electrically connected to one another and may include plugs 172a penetrating the first interlayer dielectric 144 and plugs 172b penetrating a second interlayer dielectric 146. The wordline structure 170 may further include a connection pad 173 for electrically connecting the plugs 172a to the plugs 172b. The wordlines 174 may be disposed on the second interlayer dielectric 146 formed on the first interlayer dielectric 144 to cross over the bitlines 154, i.e., extend along the first direction X. The wordlines 174 may be electrically connected to the gate conductive pattern 134a via the third plugs 172. The foregoing first, second, and third plugs 152, 162, and 172 may be made of a substantially same metallic material, and may include plugs that may be formed by means of the same plug forming process.

The semiconductor memory device 100 may further include a bonding layer 142 formed to bond the memory substrate 120′ to the peripheral circuit substrate 190. The bonding layer 142 may be made of, e.g., an oxide.

The connection structure connecting the peripheral circuit transistors in the peripheral circuit substrate 190 to the memory transistors in the memory substrate 120′ may include a plurality of plugs. For example, the connection structure may include plugs connecting the bits lines 154 to the peripheral circuit transistors, plugs connecting the source line 164 to the peripheral circuit transistors, and plugs connecting the wordlines 174 to the peripheral circuit transistors. These plugs may be formed to penetrate the bonding layer 142 in the peripheral circuit region “b”. For example, as illustrated in FIGS. 1-2, the connection structure may include fourth plugs 180 formed to penetrate the bonding layer 142 in the peripheral circuit region “b”. As further illustrated in FIG. 2, one end of the fourth plugs 180 may be connected to the source line 164, and the other end thereof may be connected to peripheral circuit interconnections 198 formed at the peripheral circuit substrate 190. The fourth plugs 180 may be made of the same material as the first, second, and third plugs 152, 162, and 172. In addition, the fourth plugs 180 may be formed during a process of forming the first, second, and third plugs 152, 162, and 172.

The bottom architecture 190, i.e., the peripheral circuit substrate 190, may include the peripheral circuit transistors operating the memory transistors on the memory substrate 120′. The peripheral circuit transistors may be disposed on active regions defined by device isolation layers 191, respectively. Each of the peripheral circuit transistors may have the same configuration as a typical transistor. For example, as illustrated in FIGS. 2-4, each of the peripheral circuit transistors may include a gate insulating layer 194 disposed on a semiconductor substrate, source and drain regions 192a and 192b formed in the semiconductor substrate adjacent to opposite sides of the gate insulating layer 194, a wordline 196 disposed on the gate insulating layer 194, and the peripheral circuit interconnections 198 connected to the source region 192a, the drain region 192b, and the wordline 196 by connection plugs 197.

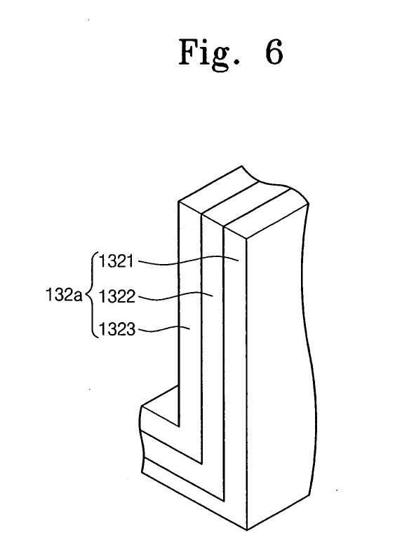

FIG. 6 illustrates a perspective view of a portion of one memory cell shown in FIG. 1. Referring to FIG. 6, a semiconductor memory device 100 may be any one of charge trap-type flash memory devices. A charge trap-type flash memory device may include a gate insulating layer with a chare trap layer. Thus, the gate insulating layer 132a of the semiconductor memory device 100 may include, e.g., sequentially deposited, a tunnel insulating layer 1321, a charge storage layer 1322, and a floating insulating layer 1323. The tunnel insulating layer 1321 may be made of silicon oxide, and the charge storage layer 1322 may be made of silicon nitride. The floating insulating layer 1323 may be made of silicon oxide or high-k dielectric material.

A method of fabricating the above-described semiconductor memory device 100 will now be described below in detail. Duplicate explanations of the configuration of the semiconductor memory device 100 will be omitted.

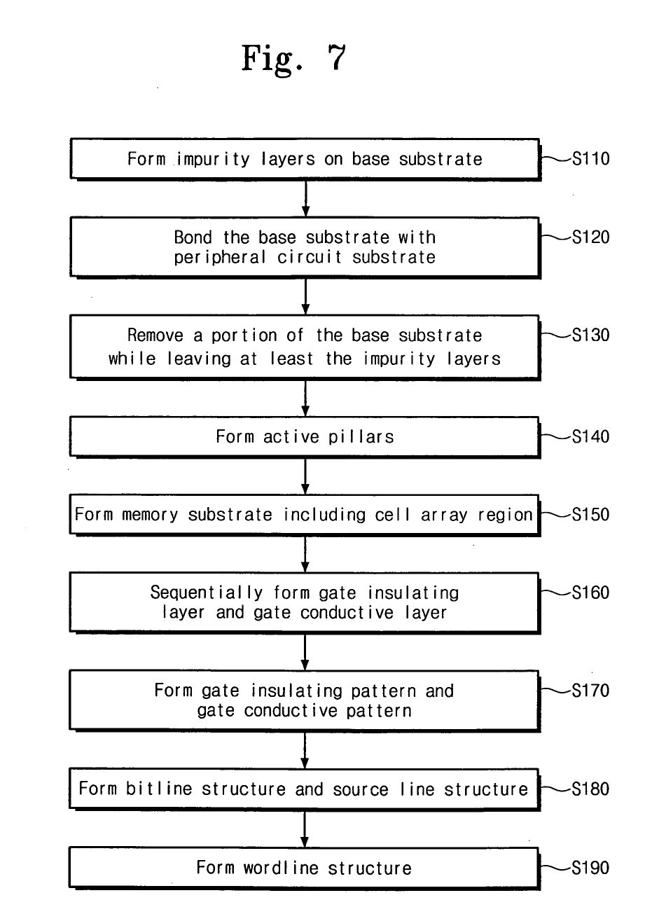

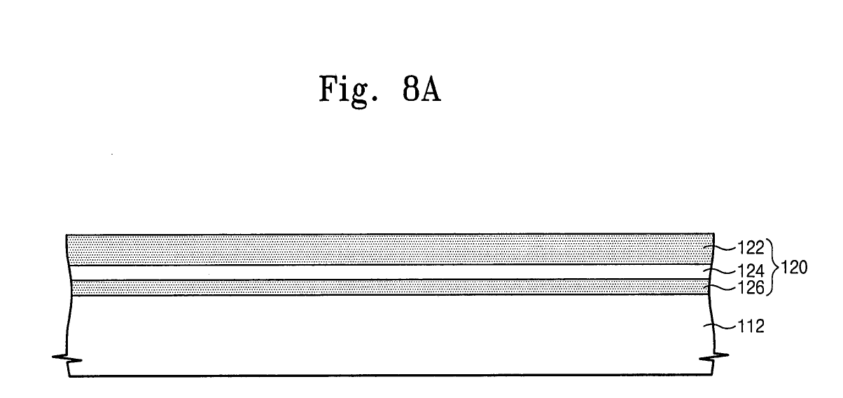

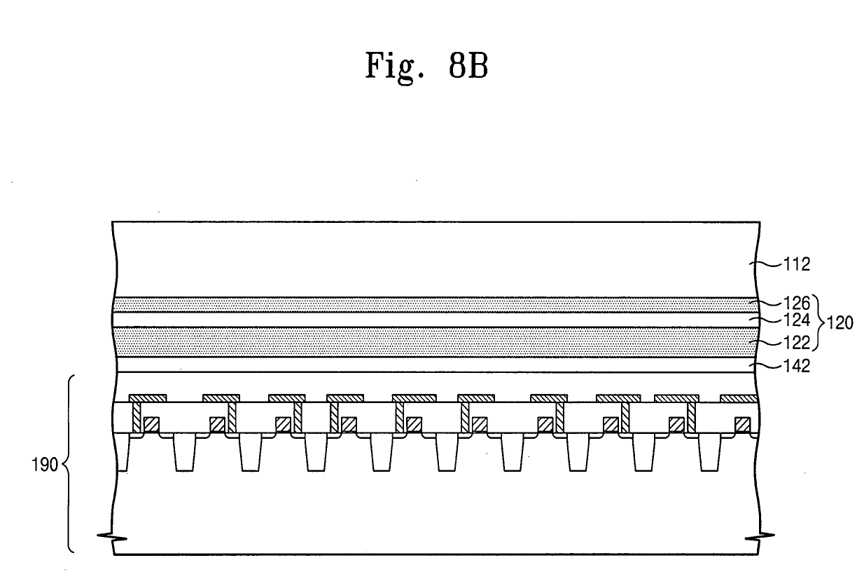

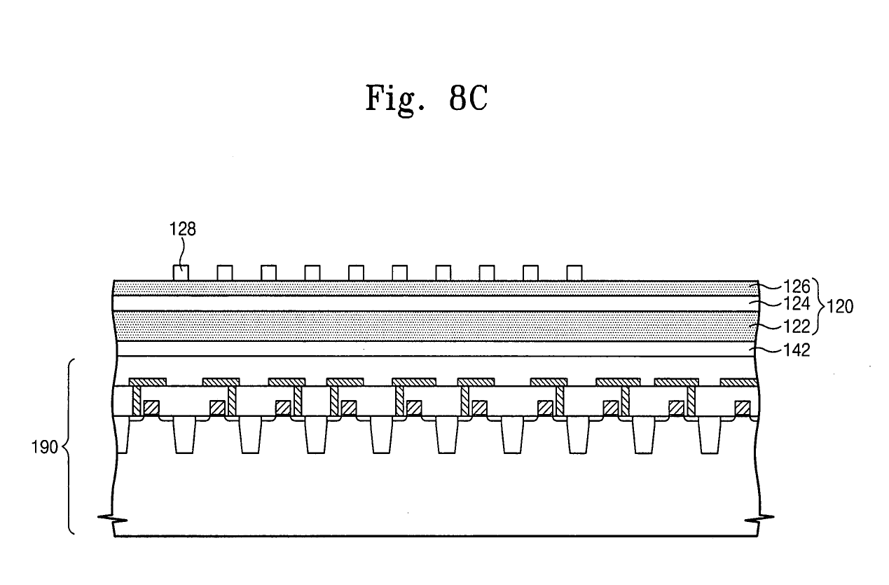

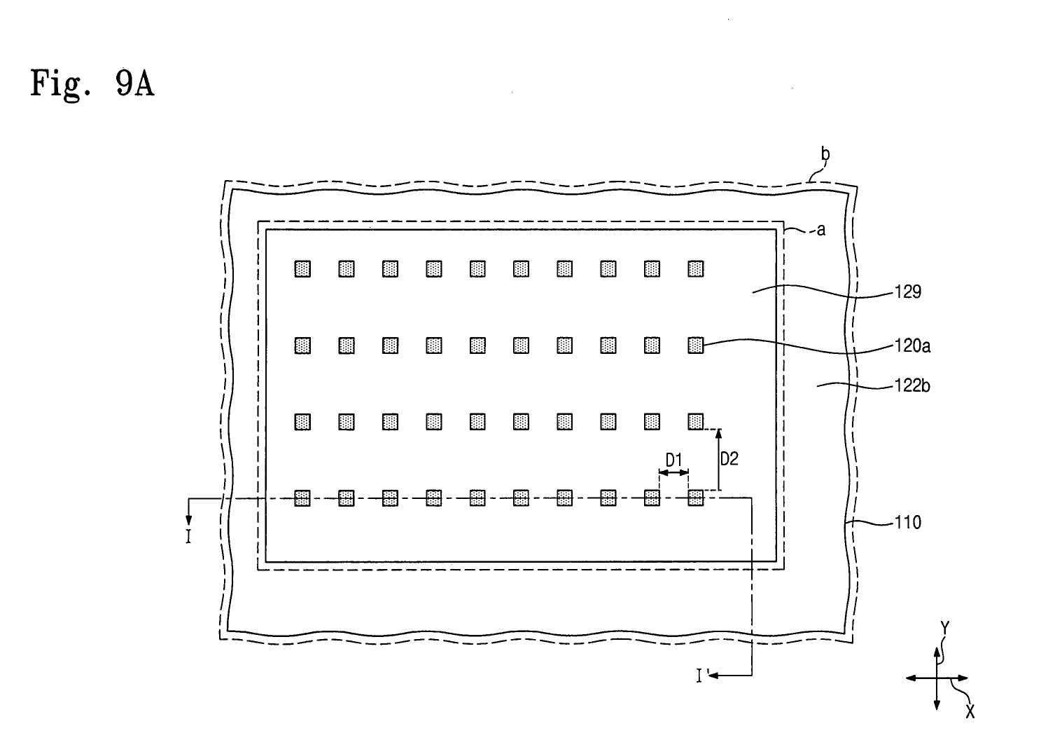

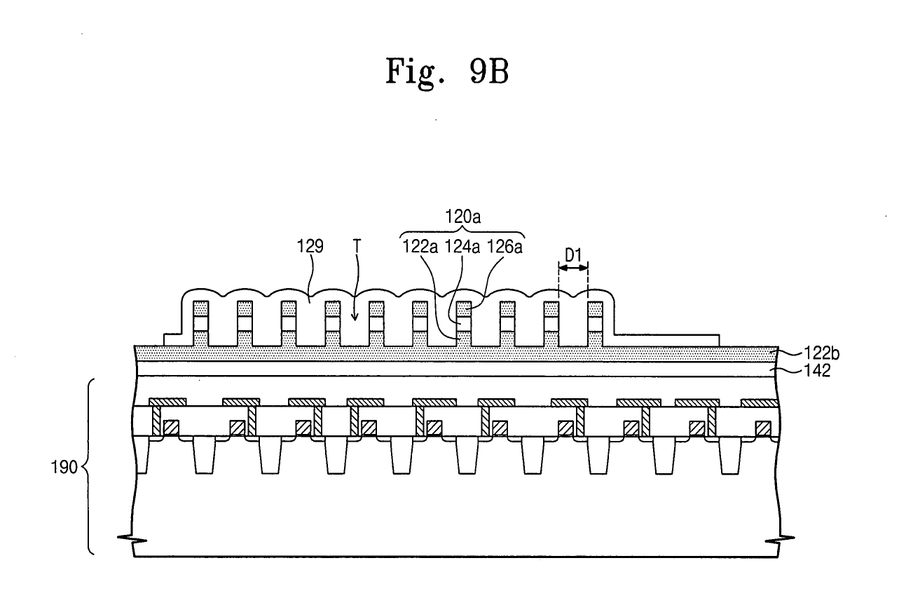

FIG. 7 illustrates a flowchart of a method of fabricating a semiconductor memory device according to the example embodiments. FIGS. 8A through 8C illustrate cross-sectional views along line I-I′ of FIG. 1, respectively, which illustrate a method of forming a bonded substrate according to the present invention. FIGS. 9A through 14A illustrate top plan views of a method of fabricating a semiconductor memory device according to the present invention. FIGS. 9B through 14B illustrate cross-sectional views along line I-I′ of respective FIGS. 9A through 14A.

Referring to FIGS. 7 and 8A, impurity layers 120 may be formed on a base substrate 112 (S110). The base substrate 112 may be provided to form the above-described memory substrate 120′. The base substrate 112 may be a single-crystalline bulk silicon substrate. For example, the base substrate 112 may be a substrate doped with P-type impurities.

Forming the impurity layers 120 may include forming a source layer 122 and forming a drain layer 126. In addition, forming the impurity layers 120 may further include forming a channel layer 124 between the source layer 122 and the drain layer 126. The source layer 122 and the drain layer 126 may be formed of a material having the same conductivity type, and the channel layer 124 may be formed of a material having a different conductivity type from the source layer 122.

The impurity layers 120 may be formed by means of ion implantation processes performed under different energy conditions. For example, the energy conditions of an ion implantation process performed on the base substrate 112 to form the source layer 122 and an ion implantation process performed to form the drain layer 126 may be different from each other, e.g., such that the source and drain layer 122 and 126 may be formed at different heights in the base layer 112. The channel layer 124 may be formed between the source layer 122 and the drain layer 126 by means of an ion implantation process. Alternatively, a region of the base substrate 112 between the source layer 122 and the drain layer 126 may be used as the channel layer 124 without performing an ion implantation process. The source layer 122 may be an impurity layer provided to form a source region (122a of FIG. 5) of each of the active pillars 120a and a common source region (122b′ of FIG. 5). Therefore, a thickness of the source layer 122 may be controlled considering a thickness of the source region 122a and a thickness of the common source region 122b′, e.g., the source layer 122 may be thicker than the drain layer 126.

Referring to FIGS. 7 and 8B, the base substrate 112 including the impurity layers 120 may be bonded onto the peripheral circuit substrate 190 (S120). That is, the bonding layer 142 may be formed on a top surface of the peripheral circuit substrate 190. The bonding layer 142 may be formed, e.g., by means of a thermal diffusion process or a deposition process. A surface of the base substrate 112 contacting the impurity layers 120 may be in contact with the peripheral circuit substrate 190 via the bonding layer 142, e.g., the source layer 122 may be in direct contact with the bonding layer 142. In this case, the peripheral circuit substrate 190 may be a substrate where the above-described peripheral circuit transistors may be formed. The base substrate 112 and the peripheral circuit substrate 190 may be bonded, e.g., by means of a conventional silicon direct bonding (SDB) technique.

Referring to FIGS. 7 and 8C, a portion of the base substrate 112 may be removed while leaving at least the impurity layers 120 on the bonding layer 142 (S130). For example, a portion of the base substrate 112 may be removed, so only the impurity layers 120 may remain on the bonding layer 142. In another example, after a first portion of the base substrate 112 is removed to leave the impurity layers 120 and a second portion of the base substrate 112 on the bonding layer 142, at least part of the second portion of the base substrate 112 may be removed from the bonding layer 142. The at least part of the second portion of the base substrate 112 may be removed, e.g., by means of a chemical mechanical polishing (CMP) process. Thereafter, a photoresist pattern 128 may be formed on the impurity layers 120, e.g., directly on the drain layer 126.

Referring to FIGS. 7, 9A, and 9B, vertical active pillars 120a may be formed on the bonding layer 142 (S140). For example, a patterning process may be performed using the photoresist pattern 128 as a mask to successively pattern the drain layer 126, the channel layer 124, and the source layer 122. As a result, a trench T may be formed to expose at least a portion of the source layer 122, as illustrated in FIG. 9B. In the patterning process, a distance between the active pillars 120a disposed in the first direction X, i.e., the first distance D1, may be smaller than a distance between the active pillars 120a disposed in the second direction Y, i.e., the second distance D2.

A bottom of the trench T may be lower than a top surface of the source layer 122. In other words, the patterning process may remove only a portion of the source layer 122 between adjacent photoresist patterns 128, so a bottom of the trench T may be defined at a predetermined depth of the source layer 122. Accordingly, the source layer 122 may be patterned to define a preliminary common source region 122b on the bonding layer 142, i.e., an unpatterned lower portion of the source layer 122, and the source regions 122a extending vertically from the preliminary common source region 122b. Therefore, the vertical active pillars 120a may extend from the preliminary common source region 122b. Each of the active pillars 120a may include the source region 122a, channel region 124a, and drain region 126a sequentially stacked on the preliminary common source region 122b.

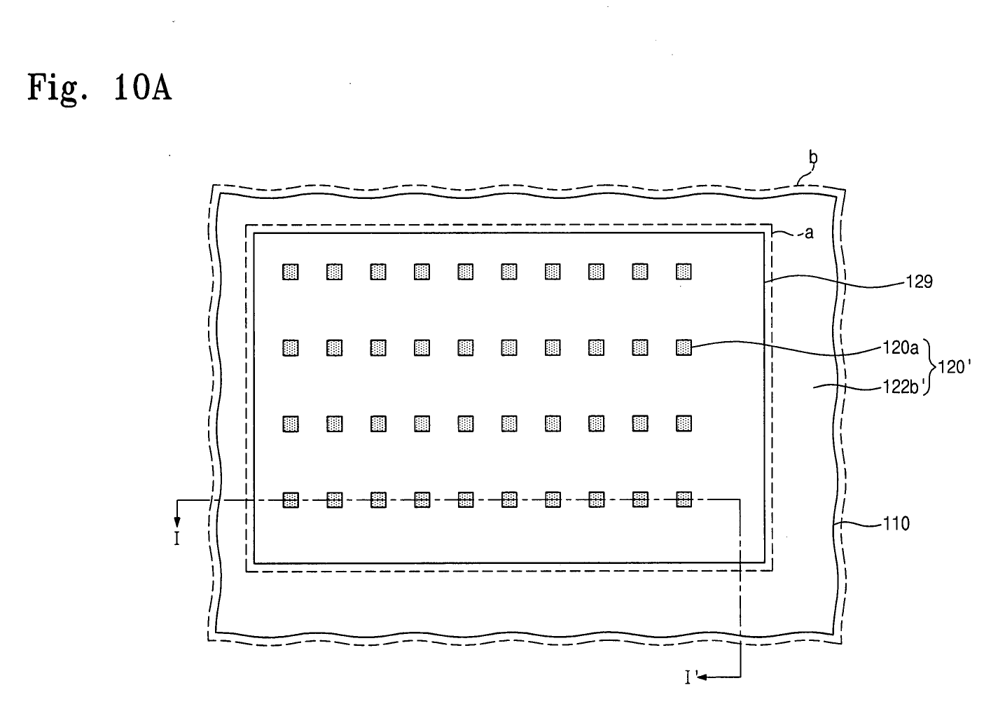

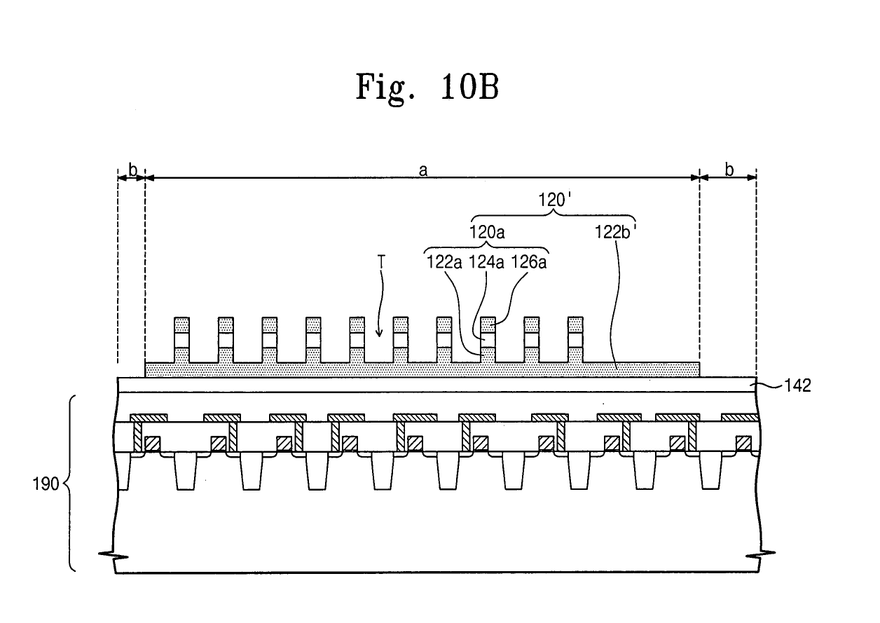

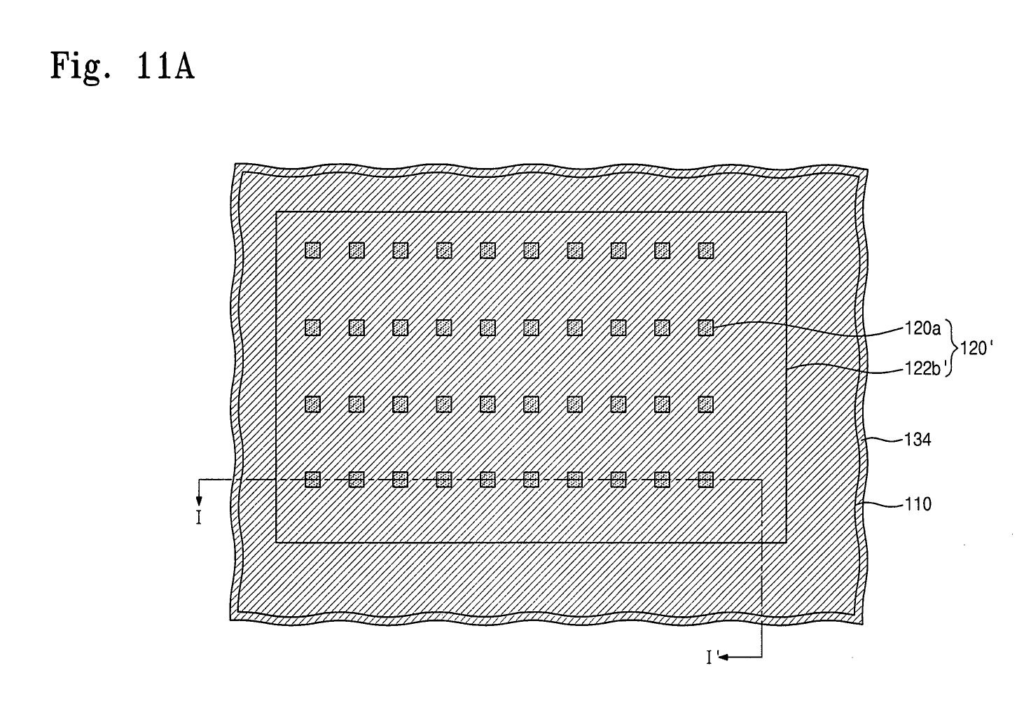

It is noted that the bottom of the trench T may be higher than a bottom surface of the source layer 122, i.e., relative to the bonding layer 142, thereby defining the preliminary common source region 122b on the bonding layer 142. The preliminary common source region 122b may be commonly connected to the source regions 122a of the respective vertical active pillars 120a. A thickness of the common source region (122b′ of FIG. 10B) and a thickness of the source region 122a may be controlled according to the bottom height of the trench T. For this reason, considering a thickness of the source region 122a and a thickness of the preliminary source region 122b, a height of the bottom of the trench T relative to the bonding layer 142 may be between heights of top and bottom surfaces of the source layer 122, as measured with respect to a common reference point on the bonding layer 142. After removing the photoresist pattern 128, as illustrated in FIG. 9B, a photoresist pattern 129 may be formed on the resultant structure to cover the active pillars 120a and a space therebetween. Forming the photoresist pattern 129 may include forming a photoresist layer and removing the photoresist layer on the cell array region “a” and the peripheral circuit region “b”.

Referring to FIGS. 7, 10A, and 10B, the memory substrate 120′ including the cell array region “a” with the memory transistors may be completed (S150). For example, as illustrated in FIG. 10, the preliminary common source region 122b may be patterned using the photoresist pattern 129 as an etching mask to expose a portion of the bonding layer 142 on the peripheral circuit region “b”. Accordingly, the memory substrate 120′ including the common source region 122b′ connected to the source region 122a of the active pillars 120a may be formed by means of this patterning process.

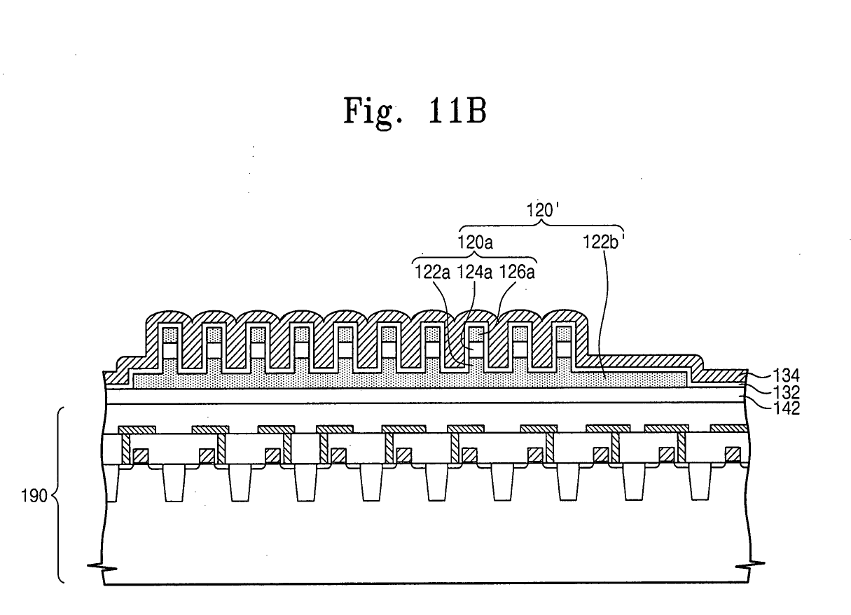

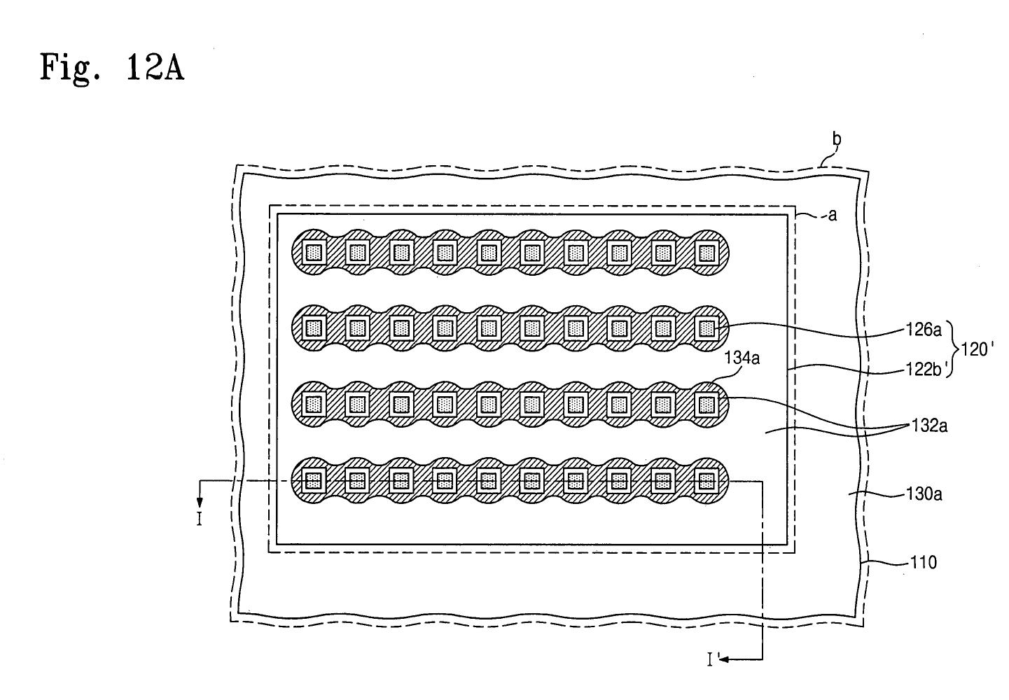

Referring to FIGS. 7, 11A, and 11B, a gate insulating layer 132 and a gate conductive layer 134 may be sequentially formed on the resultant structure where the memory substrate 120′ is formed (S160). For example, the gate insulating layer 132 may be, e.g., conformally, formed on the entire surface of the resultant structure where the memory substrate 120′ is formed. Forming the gate insulating layer 132 may include, e.g., performing a thermal oxidation process or a chemical vapor deposition (CVD) process. The gate insulating layer 132 may be formed, e.g., of one or more of silicon oxide, haffilium oxide, haffiium silicate, zirconium oxide, zirconium silicate, aluminum oxide, and aluminum silicate. The gate conductive layer 134 may be formed on the entire surface of the gate insulating layer 132. The gate conductive layer 134 may be, e.g., conformally, formed on the gate insulating layer 132. Forming the gate conductive layer 134 may include, e.g., performing a CVD process. The gate conductive layer 134 may be formed, e.g., of polysilicon. The gate conductive layer 134 may be formed of a material having superior step coverage to fill up the trench T.

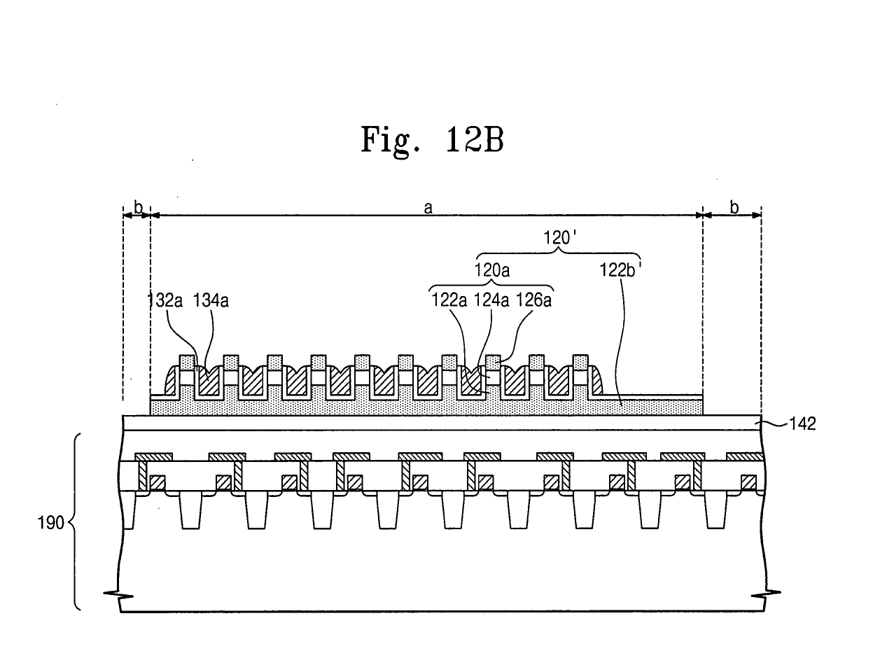

Referring to FIGS. 7, 12A, and 12B, the entire surface of the gate conductive layer 134 may be etched to form gate conductive patterns 134a surrounding the gate insulating patterns 132a and the active pillars 120a on the memory substrate 120′(S170). For example, the entire surface of the resultant structure where the gate conductive layer 134 is formed may be etched to expose top surfaces of the active pillars 120a in the cell array region “a” and the bonding layer 142 in the peripheral circuit region “b”. Etching the gate conductive layer 134 may include selectively etching the gate insulating layer 132 and the gate conductive layer 134 using an etch recipe having a lower etch rate for the active pillars 120a than for the gate insulating layer 132 and the gate conductive layer 134.

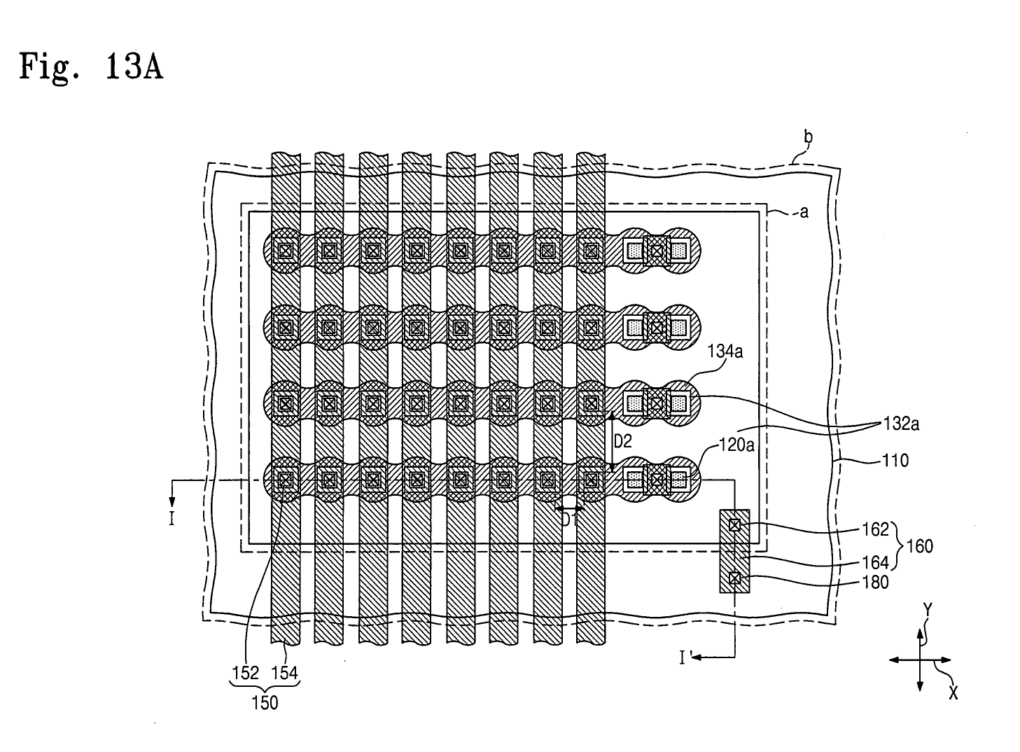

Referring to FIGS. 7, 13A, and 13B, a bitline structure 150 and a source line structure 160 may be formed (S180). For example, after forming the gate conductive layer 134a, the method may further include forming the first interlayer dielectric 144 on the top architecture, where the gate conductive pattern 134a may be formed, and planarizing a surface of the first interlayer dielectric 144. Forming the bitline structure 150 may include forming first plugs 152 to be connected to top surfaces of the drain regions 126a of the active pillars 120a through the first interlayer dielectric 144, respectively, and forming bitlines 154 connected to the first plugs 152 on the first interlayer dielectric 144 and crossing the gate conductive patterns 134a. The bitlines 154 may be electrically connected to the drain regions 126a of the active pillars 120a by the first plugs 152, respectively.

Forming the source line structure 160 may include forming second plugs 162 to be connected to the common source region 122b′ through the first interlayer dielectric 144 and through the gate insulating pattern 132a, as illustrated in FIG. 13B. Next, the source line 164 may be formed on the first interlayer dielectric 144 to be connected to the second plugs 162. The second plugs 162 may be formed during the formation of the first plugs 152. The source line 164 may be electrically connected to the common source region 122b′ by the second plugs 162.

The connection structure may be formed to electrically connect the bitlines 154 and the source line 164 to the peripheral circuit patterns 198 of the bottom architecture 190. For example, forming the connection structure may include forming plugs (not shown) to electrically connect the plugs 152 of the bitline structure 150 to the peripheral circuit patterns 198 through the bonding layer 142 on the peripheral circuit region “b”. In another example, forming the connection structure may include forming the fourth plug 180 to electrically connect the source line 162 to the peripheral circuit patterns 198 through the bonding layer 142 on the peripheral circuit region “b”.

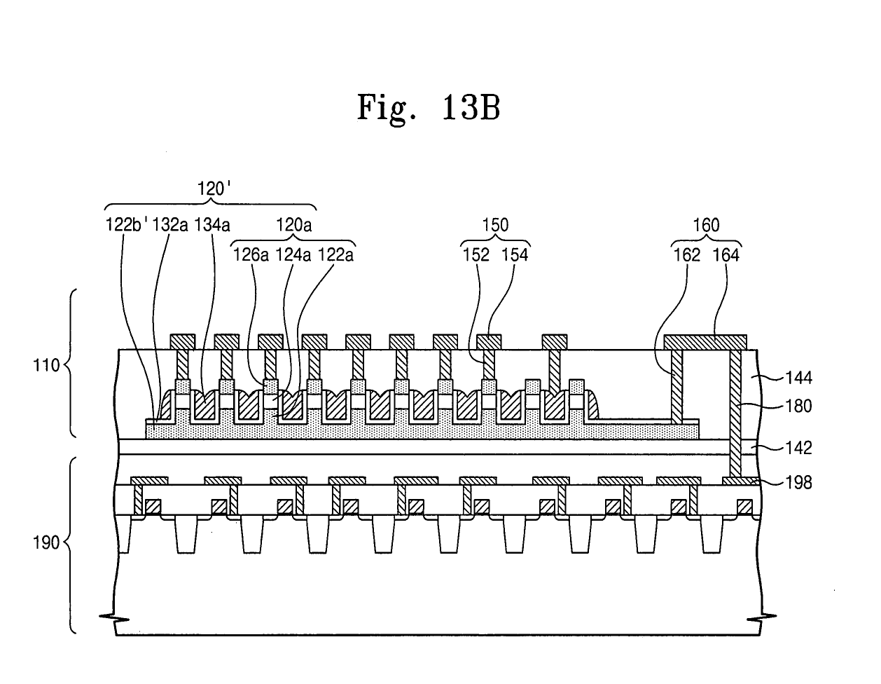

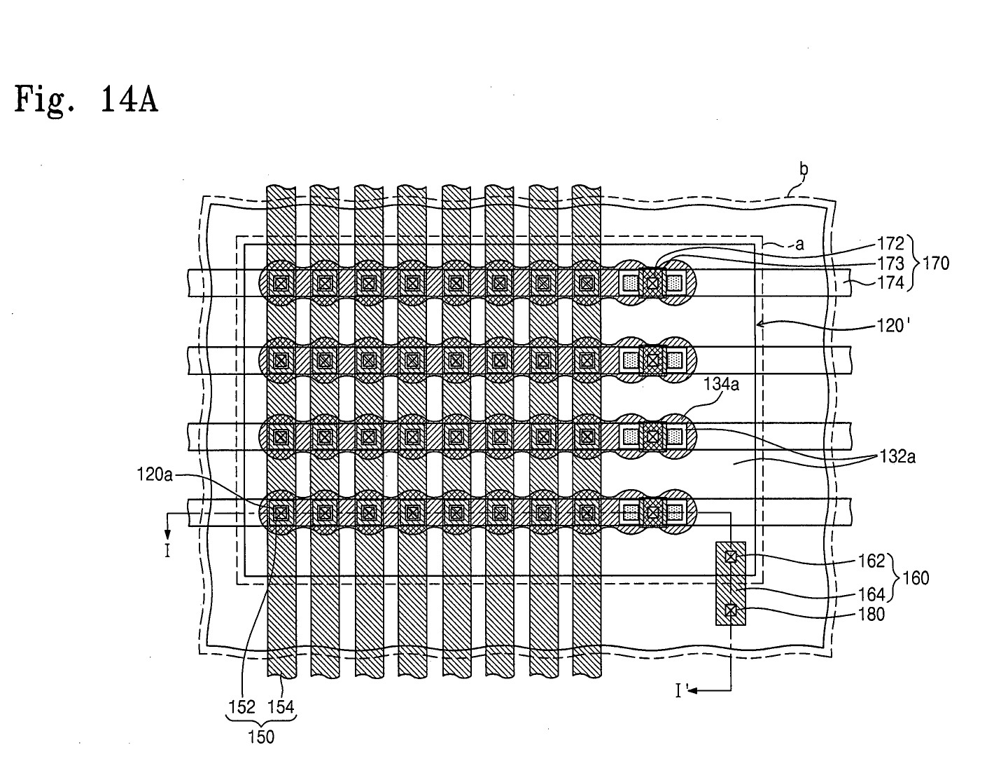

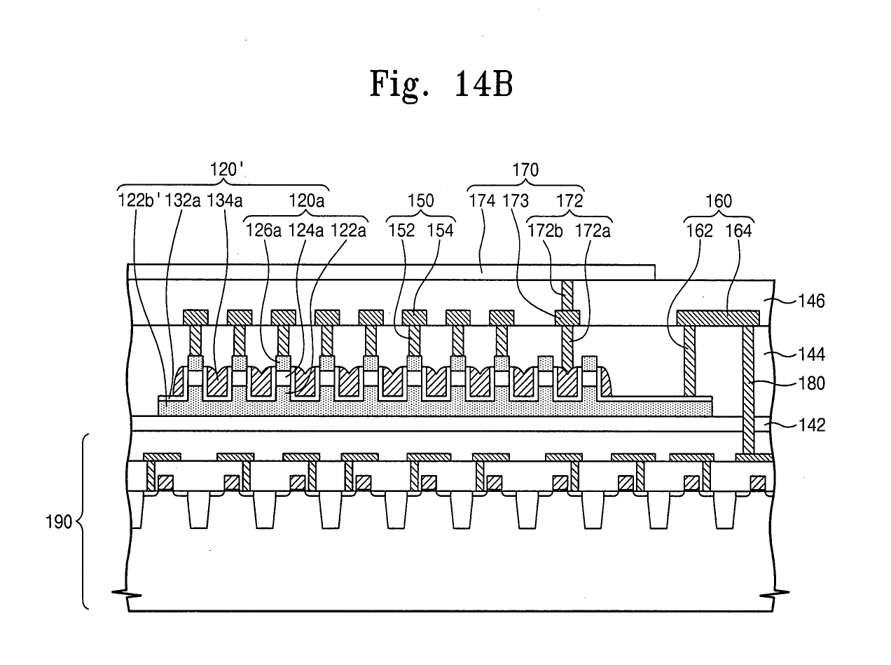

Referring to FIGS. 7, 14A, and 14B, a wordline structure 170 may be formed (S190). For example, the method may include forming the second interlayer dielectric 146 on the resultant structure, where the bitline structures 150 and the source line structure 160 is formed, and planarizing a surface of the second interlayer dielectric 146. The method may include forming third plugs 172 to be connected to a portion of the gate conductive pattern 134a between the active pillars 120a through the second interlayer dielectric 146 and forming wordlines 174 to be connected to the third plugs 172 on the second interlayer dielectric 146. The third plugs 172 may include the plug 172a penetrating the first interlayer dielectric 144 and the plug 172b connected to the plug 172a and penetrating the second interlayer dielectric 146. The plug 172a may be formed during the formation of the first and second plugs 152 and 162. Forming the wordline structure 170 may further include forming the connection pad 173 to electrically connect the plug 172a penetrating the first interlayer dielectric 144 to the plug 172b penetrating the second interlayer dielectric 146. The wordlines 174 may be formed to cross the bitlines 154 on the second interlayer dielectric 146. The method may include forming a connection structure to electrically connect the wordlines 174 to the peripheral circuit patterns 198. Forming the connection structure may include plugs (not shown) to electrically connect the wordlines 174 to the peripheral circuit patterns 198 of the peripheral circuit substrate 190 through the bonding layer 142 on the peripheral circuit region “b”.

As set forth above, example embodiments of the present invention may provide a semiconductor memory device including the memory substrate 120′ with the memory transistors including vertical active pillars 120a and the peripheral circuit substrate 190 with the peripheral circuit transistors operating the memory transistors without using a SOI substrate. The channel region 124a of the active pillars 120a may be electrically isolated by the source region 122a, drain region 126a, and gate insulating pattern 132a to be used as a charge storage element of a capacitorless memory device, e.g., DRAM. Thus, example embodiments of the present invention may provide a semiconductor memory device having a capacitorless DRAM structure.

FIG. 15 illustrates a block diagram of an electronic system including a semiconductor memory device according to the example embodiments. The semiconductor memory device may be provided to a memory card 200 for supporting a massive data storage capacity. The memory card 200 may include a memory controller 220 configured to control general data exchange between a host and a multi-bit flash memory device 210.

For example, a SRAM 221 may be used as an operation memory of a central processing unit (CPU) 222. A host interface (Host I/F) 223 may include a data exchange protocol of the host connected to the memory card 200. An error correction code block (ECC) 224 may detect and correct error included in data read out of the flash memory device 210. A memory interface (Memory I/F) 225 may interface with the flash memory device 210. The CPU 222 may execute general control operations for data exchange of the memory controller 220. A ROM (not shown) configured to store code data for interface with the host may be further provided in the memory card 200. Although not shown in the figure, it is apparent to those skilled in the art that the memory card 200 may further include a ROM storing code data for interface with the host. For example, a flash memory device according to the present invention may be provided for a memory system, e.g., a solid state disk (SSD).

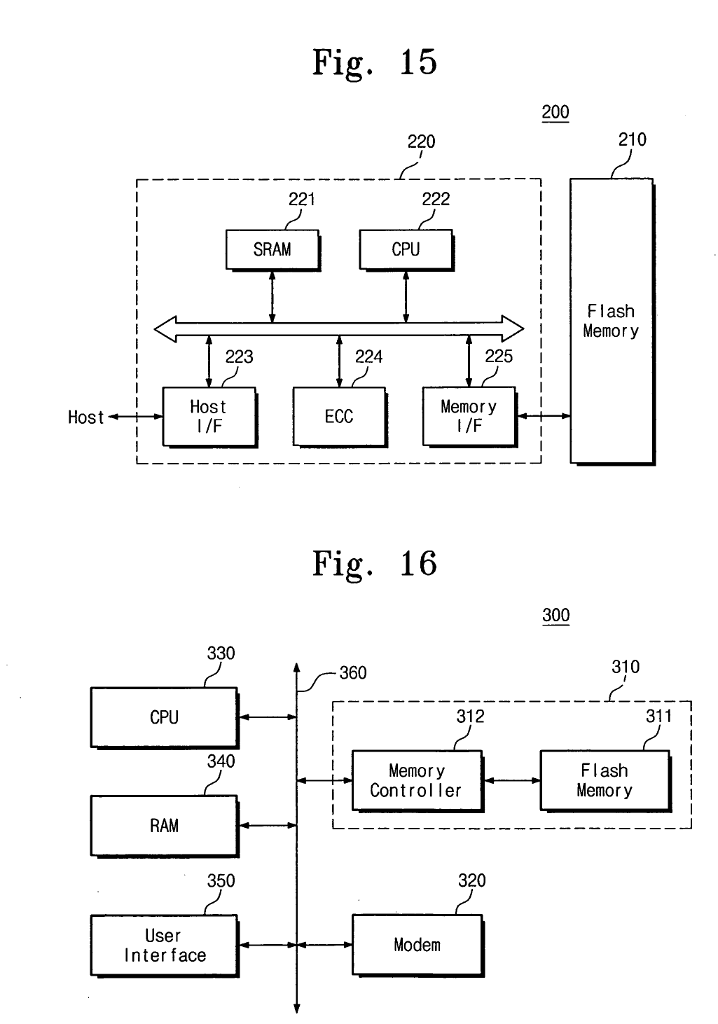

FIG. 16 illustrates a block diagram of an information processing system including a flash memory system according to example embodiments. The flash memory system may be installed in an information processing system 300, e.g., a mobile device or a desktop computer. The information processing system 300 may include a flash memory device 311 and a memory controller 312 configured to control the flash memory device 311.

The information processing system 300 may include a flash memory system 310, a modem 320 electrically connected to a system bus 360, a central processing unit (CPU) 330, a RAM 340, and a user interface 350. The flash memory system 310 may have a substantially same configuration as the above-described memory system or flash memory system. Data processed by the CPU 330 or externally input data may be stored in the flash memory system 310. The flash memory system 310 may include a solid state disk (SSD). In this case, the information processing system 300 may stably store massive data in the flash memory system 310. With the increase in reliability, the flash memory system 310 may reduce resources required for error correction to provide a high-speed data exchange function to the information processing system 300. Although not shown in the figure, it is apparent to those skilled in the art that the information processing system 300 may further include, e.g., an application chipset, a camera image processor (CIS), and an input/output device.

A flash memory device or a memory system according to the present invention may be packaged using various types of packages. For example, a flash memory device or memory controller according to the present invention may be packaged using packages such as PoP (Package on Package), Ball grid arrays (BGAs), Chip scale packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), Thin Quad Flatpack (TQFP), System In Package (SIP), Multi Chip Package (MCP), Wafer-level Fabricated Package (WFP), Wafer-Level Processed Stack Package (WSP), and the like.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1. A semiconductor memory device, comprising:
a memory substrate including memory transistors and vertical active pillars, the vertical active pillars defining active regions of the memory transistors;
a peripheral circuit substrate including peripheral circuit transistors;
a bonding layer interposed between the memory substrate and the peripheral circuit substrate; and
a connection structure electrically connecting the memory transistors to the peripheral circuit transistors.

2. The semiconductor memory device as claimed in claim 1, wherein the active pillars are single-crystalline structures extending vertically with respect to the memory substrate, and the memory transistors have vertical transistor structures.

3. The semiconductor memory device as claimed in claim 1, wherein each of the active pillars includes a source region and a drain region spaced apart from each other and a channel region between the source region and the drain region.

4. The semiconductor memory device as claimed in claim 3, wherein the source region and the drain region have a same conductivity type and are spaced apart from each other along a direction normal to the memory substrate, and the source region and the channel region have different conductivity types.

5. The semiconductor memory device as claimed in claim 3, wherein each memory transistor includes a gate pattern surrounding the active pillar and a gate insulating layer interposed between the gate pattern and the active pillar, the source and drain regions being at lower and upper portions of the active pillar, respectively.

6. The semiconductor memory device as claimed in claim 5, wherein the channel region is electrically isolated by the gate insulating layer, the source region, and the drain region, the channel region being configured to store charges.

7. The semiconductor memory device as claimed in claim 5, wherein the gate insulating layer includes a charge storage structure for storing charges.

8. The semiconductor memory device as claimed in claim 7, wherein the gate insulating layer includes a tunnel insulating layer, a charge storage layer, and a blocking insulating layer.

9. The semiconductor memory device as claimed in claim 5, wherein a thickness of the gate pattern is smaller than a length of the active pillar, the thickness and length being measured along a direction normal to the memory substrate.

10. The semiconductor memory device as claimed in claim 5, wherein a distance between a bottom surface of the gate pattern and the bonding layer is smaller than a distance between a top surface of the source region and the bonding layer, the bottom surface of the gate pattern facing the bonding layer, and the top surface of the source region facing away from the bonding layer.

11. The semiconductor memory device as claimed in claim 3, wherein the memory substrate includes a common source region connecting the source regions of the active pillars.

12. The semiconductor memory device as claimed in claim 3, wherein each of the memory transistors includes a gate pattern surrounding the active pillar, and the semiconductor memory device further includes:
a wordline structure connected to the gate pattern;
a bitline structure connected to the drain regions; and
a source structure connected to a common source region,
wherein the wordline structure, the bitline structure, and the source structure are electrically connected to the peripheral circuit transistor via the connection structure.

13. The semiconductor memory device as claimed in claim 1, wherein the connection structure includes a plug penetrating at least the bonding layer, the plug being external to the memory substrate.

14-20. (canceled)
